(19) United States
(12) Patent Application Publication
(10) Pub. No.: US 2021/0394440 A1
(43) Pub. Date: Dec. 23, 2021

(54) FABRICATION OF STRUCTURE FROM LOST BASE MATERIAL

(71) Applicant: University of Massachusetts, Boston, MA (US)

(72) Inventors: Alkim Akyurtlu, Arlington, MA (US); Richard M. Osgood, III, Winchester, MA (US); Guinevere M. Strack, Hudson, MA (US); Yassine AitElAoud, Boston, MA (US)

(21) Appl. No.: 17/350,531

(22) Filed: Jun. 17, 2021

Related U.S. Application Data
(60) Provisional application No. 63/040,567, filed on Jun. 18, 2020.

(51) Int. Cl. B29C 64/153; B29C 64/295; B29C 64/393; B82Y 40/00; B33Y 70/00; B33Y 10/00; B29L 31/00

(52) U.S. Cl. CPC B29C 64/153; B29C 64/295; B29C 64/393; B29L 2031/7562; B33Y 70/00; B33Y 10/00; B82Y 40/00

(57) ABSTRACT

A scalable method of fabricating large area nanoparticle arrays is disclosed. The method uses a combination of nanofabrication and additive manufacturing techniques to fabricate ordered nanoparticle arrays on wide number of substrates, including flexible substrates. Nanosphere lithography may be used to form a monolayer of polymer nanospheres. A metal may be deposited on the nanospheres, using a physical vapor deposition technique. The nanoparticles may then be decomposed using intense pulsed light technique. Ordered nanoparticle arrays have several promising applications, for example, thin films with tailored light scattering signatures, sensors based on surface-enhanced Raman scattering, nanostructured electrode arrays, and ordered catalytic islands for nanostructure growth.

### RELATED APPLICATION

This application claims the benefit of earlier filed United States Provisional Patent Application Ser. No. 63/040,567 entitled “LARGE AREA NANOPARTICLE ARRAYS AND METHOD OF MAKING THEREOF,” (Attorney Docket No. UML2020-036-01), filed on Jun. 18, 2020, the entire teachings of which are incorporated herein by this reference.

GOVERNMENT RIGHTS: This invention was made with government support under Contract #W911QY-17-2-004, Grant #: S5131037559MN15 awarded by the Dept. of the Army, US Army Combat Capabilities Development Command Soldier Center (CCDC-SC). The government has certain rights in the invention.

### BACKGROUND

### 1. Field of the Invention

This disclosure relates generally to forming a pattern such as via base material on other material on substrates, and more particularly an improved method of forming nanoparticle arrays, structures, surface relief patterns, etc., on a substrate using intense pulsed light (optical signal).

### 2. Background of the Related Art

Over the recent decades, the growth of nanotechnology research has resulted in innovative work; however, the implementation of the demonstrated technologies is only possible if the fabrication process is rendered scalable. Traditional fabrications techniques, such as e-beam lithography, require highly trained experts and yield small, laboratory-scale sample sizes. Moreover, these processes are typically applied to ideal surfaces, such as Si wafers and are not readily transitioned to flexible, low temperature substrates. Furthermore, furnace-based processes require costly equipment with a limited production rate.

### BRIEF DESCRIPTION OF EMBODIMENTS

Embodiments herein include one or more scalable methods of fabricating large area nanoparticle arrays that overcomes the problems noted in the prior art. Moreover, the methods disclosed herein are applicable to wide number of substrates, including flexible or rigid substrates. The method uses combined nanofabrication and additive manufacturing techniques to fabricate ordered nanoparticle arrays on flexible substrates. Ordered nanoparticle arrays have several promising applications, for example, thin films with tailored light scattering signatures, sensors based on surface-enhanced Raman scattering, nanostructured electrode arrays, and ordered catalytic islands for nanostructure growth.

One embodiment provides a method of using: i) nanosphere lithography

(“NSL”) to form the large area array of nanoparticles and coat them and ii) the application of intense pulsed light (“IPL”) to create low thermal budget curing on low temperature substrates. NSL involves the assembly of polymer structures onto a substrate. The polymer structures can have some sort of order, for example, polystyrene beads, may be applied to a substrate via an assembly technique, such as spin coating, dip coating, and convective assembly. via spin coating. Other synthetic polymers may be used such as such as polylactide, polylactide-polyglycolide copolymers, polycaprolactones, and polyacrylates. Natural polymers such as alginate, albumin, or chitosan may also be used. The beads formed a monolayer on the substrate and packed in a hexagonal order. NSL can be used to pattern hexagonally ordered spherical shapes in materials, for example, metals. The beads can be used as a mask or can be removed to leave behind metallic holes. The beads form a template that will decompose upon application of IPL, i.e., thermally induced decomposition. The polymer is coated with a thin (nanometric) layer of metal, ranging from about 1 nm to about 500 nm thick, before the application of IPL. The metal may also range from about 5 nm to about 60 nm thick as well.

Embodiments herein further include a method comprising: via a fabricator equipment: depositing base material on a substrate; depositing metal onto the base material; and applying an optical signal to the metal, the optical signal heating the metal and decomposing the base material.

In further example embodiments, depositing base material on a substrate includes: disposing nanoparticles on the substrate using nanosphere lithography.

In yet further example embodiments, the base material is a polymer material comprising multiple nanoparticles. The polymer is selected from the group consisting of: polystyrene, polylactide, polylactide-polyglycolide copolymers, polycaprolactones, polyacrylates, poly(methyl methacrylate) (PMMA), polyethylene (PE), alginate, albumin, and chitosan.

In still further example embodiments, application of the optical signal heats the metal above a melting point of the metal material. In one embodiment, bulk (thicker) material melting points can be higher than those very thin layers (less than 50 nm) of the same material. For example, the melting point of bulk silver is 900 to 100 degree C., but this temperature drops when there is a very thin layer. This means that one would not need to heat the layer above 900 C. to melt the silver.

In yet further example embodiments, the base material includes particles such as nanosphere particles or other sized particles; the particles being a hexagonally packed monolayer on the substrate. Diameters of the particles fall within a range of about 25 nanometers to about 25 microns or other suitable value.

In one embodiment, the base material is a non-metal material such as plastic. As its name suggests, the base material provides a form from which to fabricate

In still further example embodiments, the deposited metal is a metal layer disposed on the base material; a melting point of the base material is lower than a melting point of the metal.

Further embodiments herein include, via the fabricator equipment, controlling a magnitude of energy supplied by the optical signal to the metal to produce an array of hollow metal elements.

Yet further embodiments herein include a system comprising a fabricator. The fabricator is operative to: deposit base material on a substrate; deposit metal onto the base material; and apply an optical signal to the metal, the optical signal heating the metal and decomposing the base material.

Note that any of the resources as discussed herein can include one or more computerized devices, wireless stations, mobile communication devices, servers, base stations, wireless communication equipment, communication management systems, controllers, workstations, user equipment, handheld or laptop computers, or the like to carry out and/or support any or all of the method operations disclosed herein. In other words, one or more computerized devices or processors can be programmed and/or configured to operate as explained herein to carry out the different embodiments as described herein.

Yet other embodiments herein include software programs to perform the steps and operations summarized above and disclosed in detail below. One such embodiment comprises a computer program product including a non-transistory computer-readable storage medium (i.e., any computer readable hardware storage medium) on which software instructions are encoded for subsequent execution. The instructions, when executed in a computerized device (hardware) having a processor, program and/or cause the processor (hardware) to perform the operations disclosed herein. Such arrangements are typically provided as software, code, instructions, and/or other data (e.g., data structures) arranged or encoded on a non-transitory computer readable storage medium such as an optical medium (e.g., CD-ROM), floppy disk, hard disk, memory stick, memory device, etc., or other a medium such as firmware in one or more ROM, RAM, PROM, etc., or as an Application Specific Integrated Circuit (ASIC), etc. The software or firmware or other such configurations can be installed onto a computerized device to cause the computerized device to perform the techniques explained herein.

Accordingly, embodiments herein are directed to a method, system, computer program product, etc., that supports operations as discussed herein.

One embodiment includes a computer readable storage medium and/or system having instructions stored thereon to facilitate phase noise (pre) compensation (adjustment). The instructions, when executed by computer processor hardware, cause the computer processor hardware (such as one or more co-located or disparately processor devices) to: deposit base material on a substrate; deposit metal onto the base material; and apply an optical signal to the metal, the optical signal heating the metal and decomposing the base material.

The ordering of the steps above has been added for clarity sake. Note that any of the processing steps as discussed herein can be performed in any suitable order.

Other embodiments of the present disclosure include software programs and/or respective hardware to perform any of the method embodiment steps and operations summarized above and disclosed in detail below.

It is to be understood that the system, method, apparatus, instructions on computer readable storage media, etc., as discussed herein also can be embodied strictly as a software program, firmware, as a hybrid of software, hardware and/or firmware, or as hardware alone such as within a processor (hardware or software), or within an operating system or a within a software application.

As discussed herein, techniques herein are well suited for use in the field of fabricate of structures on a substrate. However, it should be noted that embodiments herein are not limited to use in such applications and that the techniques discussed herein are well suited for other applications as well.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be embodied and viewed in many ways.

Also, note that this preliminary discussion of embodiments herein (BRIEF DESCRIPTION OF EMBODIMENTS) purposefully does not specify every embodiment and/or incrementally novel aspect of the present disclosure or claimed invention(s). Instead, this brief description only presents general embodiments and corresponding points of novelty over conventional techniques. For additional details and/or possible perspectives (permutations) of the invention(s), the reader is directed to the Detailed Description section (which is a summary of embodiments) and corresponding figures of the present disclosure as further discussed below.

### BRIEF DESCRIPTION OF THE DRAWINGS

These and other features, aspects, and advantages of the present invention will become better understood with reference to the following description, appended claims, and accompanying drawings where:

FIG. 1 is an illustration of a method where polystyrene beads (500 nm) were spin-coated onto willow glass such as flexible glass (1); gold (Au) (40 nm) was deposited using the vacuum sputter apparatus (2); and the samples were subjected to IPL: 450 V; env 5 ms; 1, μns pulse; 50% dc; platform height 25 mm (3);

FIG. 2 is an illustration of a simulated thermal profile for Au-coated PS beads assembled on silicon, where 20 pulses of high-energy density light were applied to the material; and

FIG. 3 is an illustration of a conductive nanofilm is exposed to pulses of high intensity broad spectrum light. The light is absorbed by the nanoparticles generating enough heat to cause the polymer sphere to degrade, leaving behind a metallic nanoparticle array.

FIG. 4 is an example diagram illustrating application of different pulses of an optical signal to control heating according to embodiments herein.

FIG. 5 is an example diagram illustrating deposition of base material on a substrate according to embodiments herein.

FIG. 6 is an example diagram illustrating deposition of metal on base material according to embodiments herein.

FIG. 7A is an example diagram illustrating application of optical signals to an assembly and different possible resulting structures according to embodiments herein.

FIG. 7B is an example diagram illustrating of a resulting one or more structures according to embodiments herein.

FIG. 7B is an example diagram illustrating of a resulting one or more structures according to embodiments herein.

FIG. 7C is an example diagram illustrating of a resulting one or more structures according to embodiments herein.

FIG. 8 is an example diagram illustrating a fabrication system and assembly including base material and a substrate according to embodiments herein.

FIG. 9 is an example diagram illustrating creation of a surface relief pattern in base material according to embodiments herein.

FIG. 10 is an example diagram illustrating application of metal material to a surface relief pattern according to embodiments herein.

FIG. 11 is an example diagram illustrating application of optical signals to an assembly of metal disposed on a surface relief pattern according to embodiments herein.

FIG. 12A is an example diagram illustrating application of material to a surface relief pattern and application of optical signals to an assembly of metal disposed on a surface relief pattern according to embodiments herein.

FIG. 12B is an example diagram illustrating a resulting one or more structures (surface relief pattern) disposed on a substrate according to embodiments herein.

FIG. 12C is an example diagram illustrating a resulting one or more structures (surface relief pattern) disposed on a substrate according to embodiments herein.

FIG. 13 is an example diagram illustrating example computer architecture operable to execute one or more operations according to embodiments herein.

FIG. 14 is an example diagram illustrating a method according to embodiments herein.

The foregoing and other objects, features, and advantages of the invention will be apparent from the following more particular description of preferred embodiments herein, as illustrated in the accompanying drawings in which like reference characters refer to the same parts throughout the different views. The drawings are not necessarily to scale, with emphasis instead being placed upon illustrating the embodiments, principles, concepts, etc.

### DETAILED DESCRIPTION

In one embodiment, which will be described in greater detail below, i) NSL and ii) the low thermal budget curing on low temperature substrates via the application of IPL are used together to form large area nanoparticle arrays on a substrate. The method enables the rapid, low cost fabrication of ordered or disordered 2D nanostructure arrays on a wide range of substrates. This technique overcomes the limitations of the thermal degradation known in the prior art, which requires substrates that tolerate high temperature (>550° C.). This technique extends the substrates (materials) suitable of patterning the metallic array. Moreover, the application of IPL takes place on the millisecond time scale, and even if several shots (there can be multiple pulse in a shot) are required, the entire processing time is equal to the number of applied shots. In one embodiment, an applied shot may be from about 0.01 to about 100 milliseconds. For example, ten shots applied at a rate of one shot per second would be a ten second process time, which is still significantly less than furnace process time, which is around one hour. In addition, the method disclosed herein is amendable to a roll-to-roll process manufacturing technique because it can be performed on flexible substrates and can be carried out in high throughput settings. Furnace-based processes require costly equipment with a limited production rate. Furthermore, the method disclosed herein does not use harsh chemicals or solvents (VOCs) and the polymer bead suspension is water-based and is free of VOCs, resulting in an environmentally friendly and safe process over prior art methods. In addition, the method disclosed herein does not require a wet lab, further reducing costs of manufacturing.

Additive manufacturing relies on the application of multiple layers to build the desired structure instead of removing or fusing components. In one embodiment, nanofabrication and additive manufacturing techniques are used to fabricate ordered nanoparticle arrays on flexible substrates. Ordered nanoparticle arrays have several promising applications, for example, thin films with tailored light scattering signatures, sensors based on surface-enhanced Raman scattering, nanostructured electrode arrays, and ordered catalytic islands for nanostructure growth.

In one embodiment, nanoparticles of a synthetic polymers such as polystyrene, poly(methyl methacrylate) (PMMA), polyethylene (PE) polylactide, polylactide-polyglycolide copolymers, polycaprolactones, and polyacrylates may be used. In other embodiments, natural polymers such as alginate, albumin, or chitosan may also be used. The nanoparticles may range in size from 25 nm to 25 microns.

In one embodiment, IPL, is used as an alternative to radiant heating when fabricating a respective assembly as discussed herein, provides low budget thermal curing. IPL is the application high energy density broadband light (200 nm to 1500 nm) to nanometric metallic films. Other wavelengths of IPL may be used. For instance, wavelength from about 500 to about 600 nm may be used. In another embodiment, lasers may be used. The light pulse occurs on the micro or millisecond timescale and the resultant energy is absorbed by the thin metallic thin film causing brief local heating. This method allows the local temperature to elevate enough to induce changes in the metallic film without damaging the substrate. The metallic film can reach temperatures higher than the meting temperature, which is typically lower than the bulk melting temperature due to the nanometric features of the film. The application of IPL to thin metallic films on low temperature substrates has several technological applications, with the main one being the low thermal budget curing of printed nanoparticle ink films for printed electronics applications.

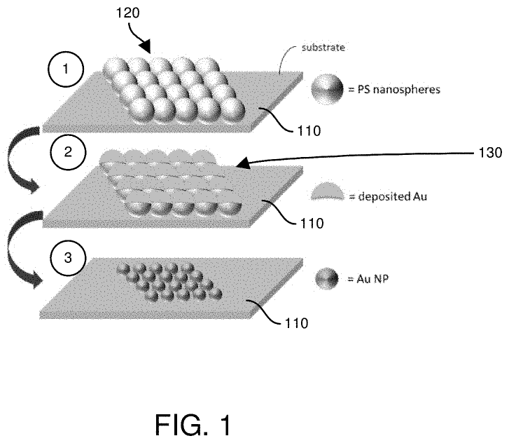

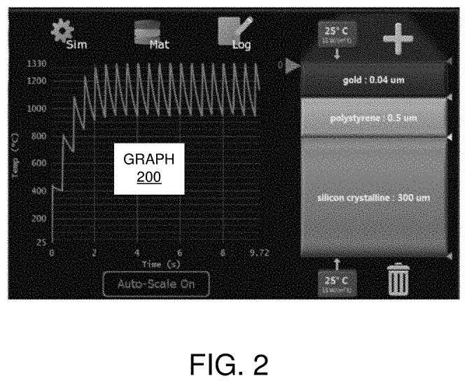

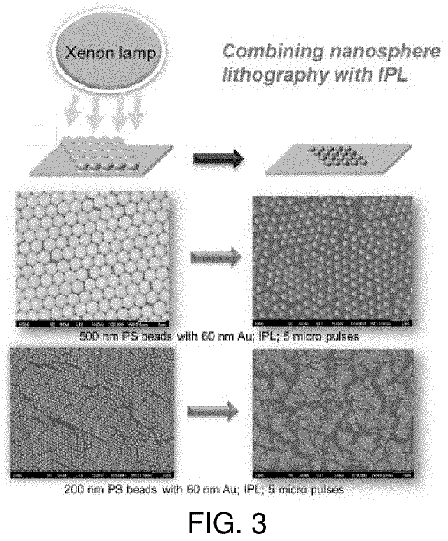

Referring now to the drawings, this method disclosed is a nanoparticle synthesis approach that leverages a low thermal budget technique in combination with nanosphere lithography (NSL). As shown in FIG. 1, polymer-based nanospheres 120 (particles of base material) are assembled on a substrate 110 and then coated with a thin layer of metal. The assembly is exposed to intense pulsed light (IPL) (i.e., one or more optical signals) on the millisecond or other suitable timescale. As shown in graph 200 of FIG. 2, the IPL causes the metal layer 130 (applied to the base material 120 such as particles) to reach high temperatures over this time scale. These high temperatures melt the metal material and induce the decomposition of the polymer (base material 120 such as particles) in direct contact with the metal layer 130. In this case, the polymer spheres serve as a nanoparticle template, which directs the formation of a metallic nanostructure via thermal decomposition. As shown in FIG. 3, the resultant metallic nanoparticles can form ordered or disorder arrays on the substrate.

The use of thermal decomposition in the past (i.e. conventional techniques) has relied on traditional heating methods such as furnaces (convection heating); therefore, the substrate material needs to tolerate temperatures higher than 500° C. In the approach described herein, the transient heating is localized and on a short time scale and does not destroy the bulk of the substrate 110.

### Example I

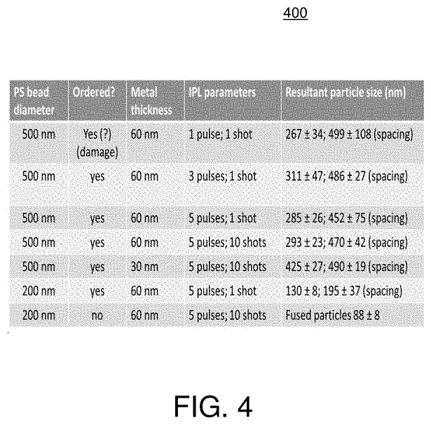

Fabrication of an ordered nanoparticle arrays was carried out using NSL and IPL. First, base material such as polystyrene (PS) nanospheres (d=200 or 500 nm) were assembled in a hexagonally packed monolayer on flexible glass (Willow® glass) or polyimide (PI) sheets by spin coating. Next, a thin (5 to 50 nm) layer of gold (Au) was deposited onto of the packed PS beads using sputtering or e-beam evaporation. Finally, IPL was applied to the sample until the PS layer was degraded and the structure of the metallic film was altered. After degradation, residual PS layer may remain up to 100% degradation of the PS layer. IPL parameters were optimized for each substrate: insufficient energy density would not cause enough local heating, while excess energy density would result in sample degradation. When IPL was applied to gold films on PS nanosphere-coated Willow glass, the PS degraded and left behind a gold nanoparticle (AuNP) smaller than the original nanosphere while retaining the original spacing. Control experiments at elevated temperatures (T=650° C.) revealed similar results, indicating that the elevated temperature caused the Au film to melt while the PS nanosphere directed the particle formation. The resultant AuNP size and spacing can be controlled by the thickness of the Au film and the diameter of the PS nanospheres (see Table 1 below). When IPL was applied to gold films on PS nanosphere-coated PI, the PS degraded and left behind ordered clusters of nanoparticles in the shape of the original nanosphere. These results demonstrate that the substrate material directs particle formation, in addition to the metallic layer thickness, PS nanosphere size, and IPL parameters. See table 400 in FIG. 4 for fabrication information. In general, FIG. 4 is an example diagram illustrating application of different pulses optical signal to control heating according to embodiments herein.

Although the present methods are described in particularity with using NSL, the method herein are applicable for a wide range of patterned polymer coatings, including but not limited to, nanoimprinting, or polymer phase separation. In the case of nanoimprinting, a polymer film, for example, PMMA or PS or certain types of UV-cross linkable films, such as SU-8 are coated onto a substrate, heated up to soften and then a stamp is used to imprint a pattern into the thin polymer film. The pattern dimensions (like the polymer spheres) can range from several microns down to less than 100 nm (nanometer). These patterns can be anything and depend on the master template, which is typically made on a wafer and then copied into a PDMS stamp. In the case of polymeric phase separation, several factors can induce phase separation and structures polymer films. For instance, a fracture phase separation technique may be used. Other parameters that may induce phase separation are temperature, solvent, and salt.

Although the method is described with particularity for forming nanostructures (such as hollow spheres) comprising an outer layer of metal such as gold (Au), the method may be used to form nanostructures (hollow or solid) comprising of a wide range of metal-based coatings. Noble metals may be used. In particular, gold (Au), silver (Ag), platinum (Pt), copper (Cu), and alloys thereof may be used. Common low temp melting alloys such as tin (Sn), indium (In), bismuth (Bi), and gallium (Ga)-based alloys. Other suitable alloys may include aluminum (Al), stainless steel, titanium (Ti), precious metals, and cobalt-chrome alloys. Low melting point glass and glass ceramics, such as those compositions disclosed in U.S. Pat. No. 6,355,586B, incorporated herein by reference, may also be used. If desired, the metal material has magnetic properties that are controlled based on a attributes of the resulting one or more structures on the substrate.

Although the method described herein is described with particularity with substrates (110) such as fabricated from glass, Kapton (polyimide), etc., embodiments herein include a variety of low temperature substrates such as thermoplastics, paper, and fabric. In addition, polymer-based substrates such as PET, liquid crystal polymer and other aromatic polyesters, fluoropolymers, PC, PEN, PU, PDMS may be used. Flexible ceramic substrates, such as ceramic fiber mats (EUREKITE), and flexible zirconia (Ribbon Cermamic; Corning) may be used. Carbon-based substrates, such as CNT paper, graphite sheets, graphene-coated flexible substrates, and carbon fiber mats may be used. Flexible conductive or ferroelectric organic crystals may also form suitable substrates.

Although the method described herein is escribed with particularity for applications for large area nanoparticle arrays and metasurfaces on flexible substrates, this method may be used for other applications. In particular, thin films with tailored light scattering signatures, sensors based on surface-enhanced Raman scattering, nanostructured electrode arrays, and ordered catalytic islands for nanostructure growth, signature management.

Therefore, it can be seen that the present invention provides a unique solution to the problem of providing a method of fabricating large area nanoparticle arrays (or structures) on a variety of substrates, including flexible substrates and temperature sensitive substrates, that overcomes the limitations of the prior art. The methods disclosed herein provide low temperature curing and are less expensive and require less costly equipment than prior art furnace-based curing and e-beam lithography methods. In addition, the methods as discussed herein are more environmentally friendly and safer than prior art methods.

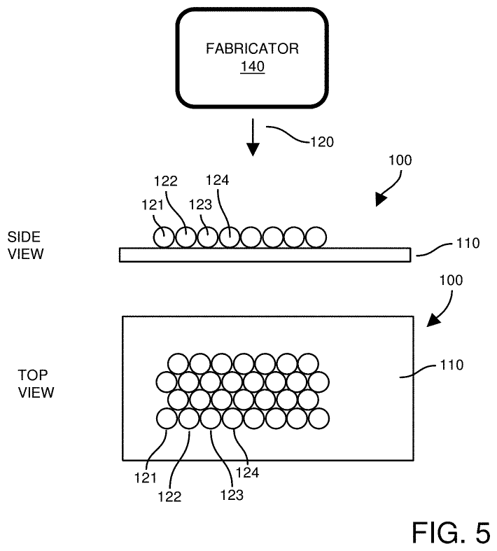

FIG. 5 is an example diagram illustrating deposition of base material on a substrate according to embodiments herein.

In this example embodiment, the fabricator 140 (such as including any suitable fabrication equipment to manufacture assemblies as discussed herein) receives a substrate 110. The fabricator 140 disposes the base material 120 (such as non-electrically conductive material, plastic, non-metal material, etc.) such as particles 121, 122, 123, 124, etc., of any shape on the substrate 110. In one embodiment, as previously discussed, the base material 120 of nanoparticles (such as particles 121, 122, 123, 124, etc.) is fabricated from a non-metal material such as plastic, resin, polymer, etc.

In one embodiment, the application of the base material 120 can include wetting the surface and/or base material 120 itself with a liquid such as water or other solvent to facilitate spreading, alignment, etc., on the respective surface of the substrate 110.

As shown in respective top view of the assembly 100 in FIG. 5, the fabricator 140 fabricates the assembly 100 to include any number of particles such forming a two dimensional array, honeycomb pattern, etc.

The base material 120 can be applied to the substrate 110 in a similar manner such as via spin coating, etc. In one embodiment, as previously discussed, the particles are mixed with a solvent such as water (or other liquid), which facilitates spreading, alignment, etc., of the particles on the surface of the substrate 110.

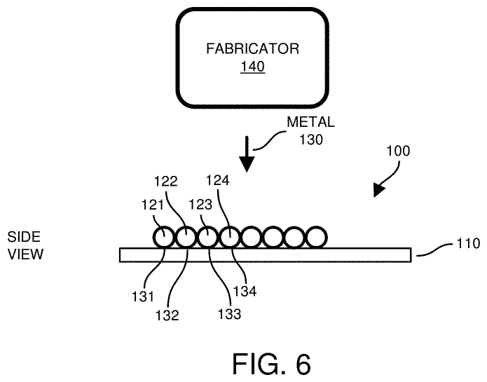

FIG. 6 is an example diagram illustrating deposition of metal material on base material according to embodiments herein.

As shown in FIG. 6, the fabricator 140 applies metal material 130 (any suitable metal such as noble metal including gold, silver, platinum, etc., or cobalt, etc.) to the assembly 100 and corresponding base material (such as non-metal nanoparticles of homogeneous material). The metal material (such as particles) can be applied in any suitable manner such as via sputtering techniques, evaporation, etc. In one embodiment, the metal material 130 includes a composition of one or more particles of metal.

Application of the metal material 130 produces a respective layer of metal on a surface of each particle. For example, the application of metal material 130 to the base material on substrate 110 via fabricator 140 results in a layer of metal material 131 on a surface of the particle 121; the application of metal 130 results in a layer of metal material 132 on a surface of the particle 122; the application of metal 130 results in a layer of metal material 133 on a surface of the particle 123; the application of metal 130 results in a layer of metal material 134 on a surface of the particle 124; and so on. The layer of metal material may be of uniform or non-uniform thickness.

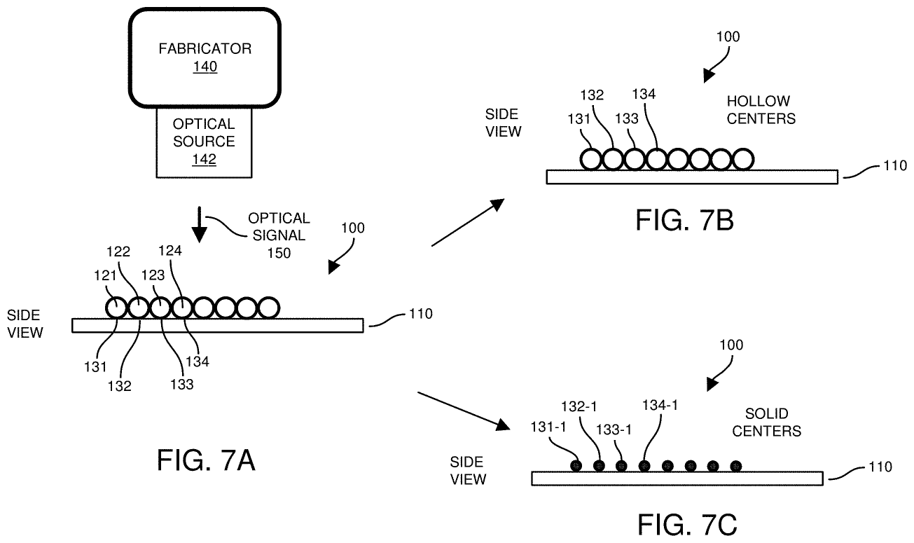

FIG. 7 is an example diagram illustrating application of optical signals to an assembly and different possible resulting structures according to embodiments herein.

As shown in FIG. 7, subsequent to deposition of metal material, the fabricator 140 controls the optical source 142 (such as laser source, flash lamp, etc., to produce optical signal 150 (such as including one or more optical pulses). The application of the optical signal 150 to the assembly 100 and corresponding metal coated particles 121, 122, 123, 124, etc., causes the layer of metal material on respective base material to briefly reach a melting point, resulting in a homogenous layer of solid metal material. The heat associated with application of the optical signal 150 to the assembly 100 further results in partially or completely degrading the original particles 121, 122, 123, 124, etc.

Application of the optical signal 150 can result in different types of final assemblies and corresponding structures. For example, in one embodiment as shown in FIG. 7A, application of the optical signal 150 (of one or more pulses of optical energy) results in any array of hollow metal structures on the substrate 100. As previously discussed, the particles 121, 122, 123, 124, etc., degrade partially or completely.

In one embodiment, the substrate material 100 (such as made from plastic or other suitable material) prevents so-called “dewetting” of the melted metal material (131, 132, 133, 134, etc.), leaving behind a hollow sphere of metal associated with each previous template particle. Note further that, cobalt or metals (metal material 130) with higher melting temperatures will heat up and degrade the polymer template (inner particles) without melting or deforming significantly. This is another way to produce the assembly 100 with multiple hollow structures.

In further example embodiments, it is noted that the term “dewettting” refers to the formation of a drop of a liquid substance on a surface. When a thin (nanometric) film of metal material is heated on the substrate 110—with a lower surface energy and a melting point higher than the temperature of the metal—the metal melts and forms little amorphous drops or disordered patches. Embodiments herein include implementing the substrate 110 as a low temperature flexible substrate, such as a polymeric film like kapton, the heat from the layers of metal material transfers not only to the polymer template that coats the substrate 110, but also to the surface of the substrate 110. As previously discussed, this brief local heating of the metal material and surrounding area softens/melts/warps the substrate 110 as it interacts with the melting metal during application of the optical signal 150 as previously discussed. In this case associated with application of optical signals 150 to the assembly 100, the layers of metal 131, 132, 133, etc., on the particles 121, 122, 123, etc., will not dewet and form a spherical drop during application of the optical signal 150, but it will leave behind a round patch or hollow hemisphere or a patterned, yet continuous metal film as shown in FIG. 7B.

Alternatively, application of sufficient heat and fabrication conditions to the assembly 100 results in the solid structures as shown in FIG. 7C, in which the layer of materials 131, 132, 133, etc., each collapse into a solid metal ball or the like.

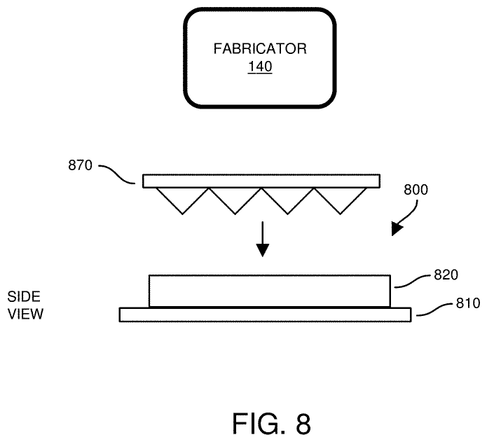

FIG. 8 is an example diagram illustrating a fabrication system and assembly including base material and a substrate according to embodiments herein.

In this example embodiment, the fabricator 140 (such as including any suitable fabrication equipment to manufacture assemblies as discussed herein) receives a substrate 810. The fabricator 140 disposes the base material 820 such as solid material or particles of any suitable shape on the substrate 810. In one embodiment, as previously discussed, the base material 820 is fabricated from a non-metal material such as plastic, resin, polymer, etc. The application of the base material 820 can include wetting the surface and/or base material 820 with a liquid such as water or other solvent.

As shown in the side view in FIG. 8, the fabricator 140 controls operation of a pattern generator 870 such as a stamp, laser, or other suitable entity that is used to create a patterned surface (surface relief pattern) on the base material 820 as further discussed below.

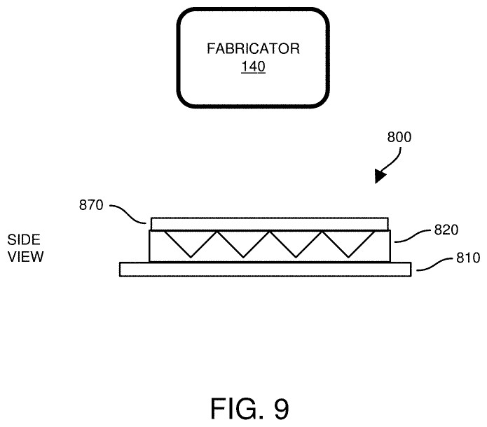

FIG. 9 is an example diagram illustrating creation of a surface relief pattern in base material according to embodiments herein.

In this example embodiment, the fabricator 140 contacts the pattern generator 870 or applies a laser signal to the base material 820, resulting in creation of a surface relief pattern in the base material 820 as further discussed below. If desired embodiments herein can include heating the base material 820 to produce a surface relief pattern in the base material 820.

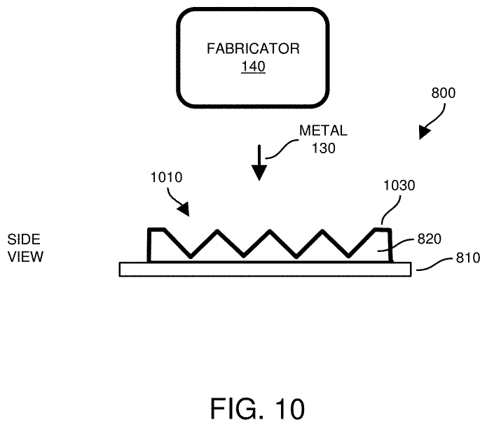

FIG. 10 is an example diagram illustrating application of metal material to a surface pattern according to embodiments herein.

Subsequent to creating a surface relief pattern 1010 on a surface of the base material 820, via metal material 130, the fabricator 140 applies a layer of metal 1030 to the surface relief pattern 1010 created on the base material 820.

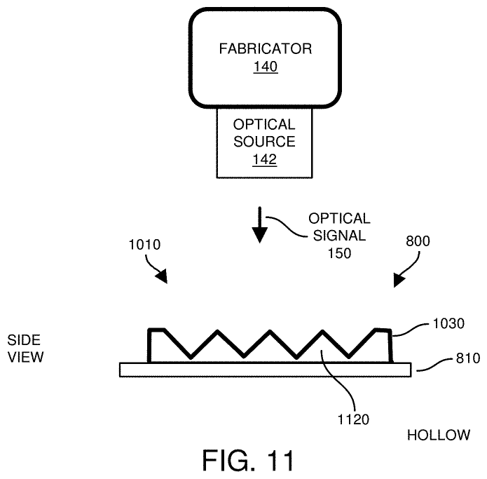

FIG. 11 is an example diagram illustrating application of optical signals to an assembly of metal disposed on a surface relief pattern according to embodiments herein.

As shown in FIG. 11, the fabricator 140 controls the optical source 142 (such as laser source, flash lamp, etc., to produce optical signal 150 (such as including one or more optical pulses). The application of the optical signal 150 to the assembly 800 and corresponding metal coated surface (layer of material 1030 on the surface relief pattern 1010), causes the layer of metal material 1030 to briefly reach a melting point, resulting in creation of a homogenous layer of solid metal material. The heat associated with application of the optical signal 150 to the assembly 800 further results in partially or completely degrading the base material 820.

Depending on an amount of applied energy via the optical signal 150 or one or more other factors, application of the optical signal 150 can result in different types of final assemblies. For example, in one embodiment, application of the optical signal 150 (of one or more pulses of optical energy) results in one or more hollow metal structure on the substrate 100. In one embodiment, in one embodiment, the base material 820 results in a hollowed cavity (volume) in place of the original base material 820. For example, as previously discussed, the layer of material 1030 on the original surface relief pattern 1010 may retain its original shape after being melted and removal of base material 820.

Additionally, or alternatively, as further discussed below, portions of the layer of material 1030 may collapse, resulting in a more solid final structure of metal disposed on the substrate 810.

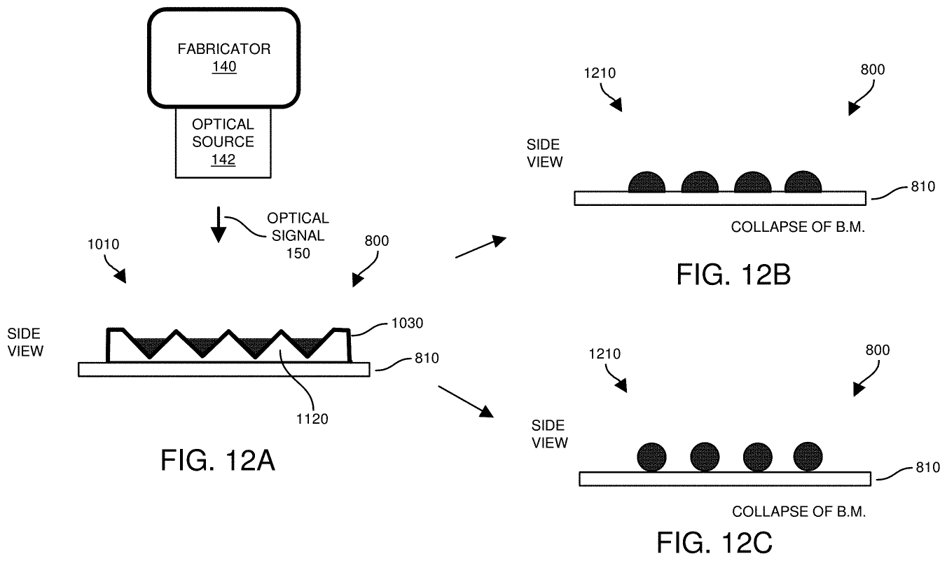

FIG. 12A is an example diagram illustrating application of material to a surface relief pattern and application of optical signals to an assembly of metal disposed on a surface relief pattern according to embodiments herein.

In this example embodiment, the fabricator 140 applies metal material 130 to the surface relief pattern 1010, resulting in metal material of different thicknesses. Application of sufficient heat via the optical signal 150 (or other suitable heat source) causes the base material 1030 to degrade, while the melted metal material 1030 create a new surface relief pattern 1210 (such as bumps or other suitable shape(s) on the substrate 810 as shown in FIG. 12B. Another example resulting surface relief pattern 1211 such as a multi-dimensional or single dimensional array of balls is shown in FIG. 12C.

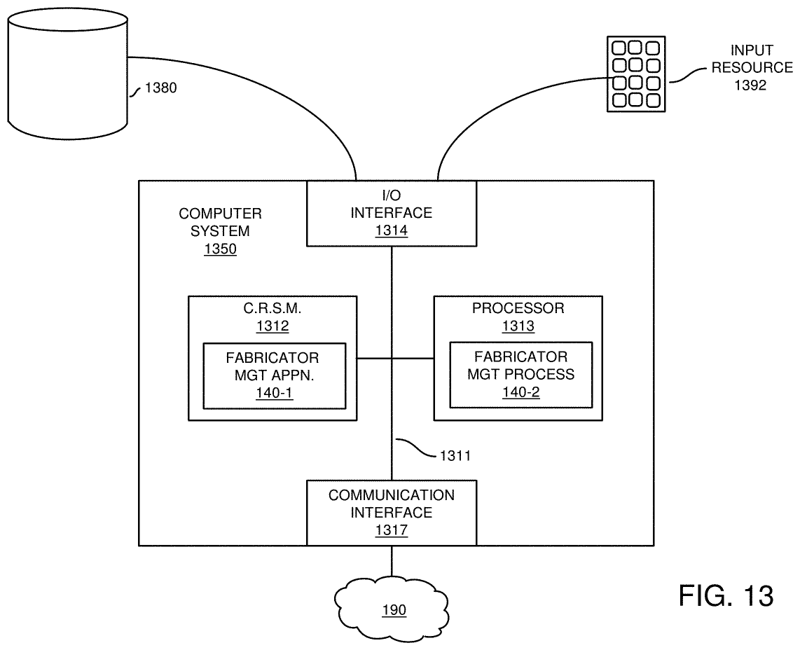

FIG. 13 is an example block diagram of a computer system for implementing any of the operations as previously discussed according to embodiments herein.

Any of the resources (such as fabricator 140, etc.) as discussed herein can be configured to include computer processor hardware and/or corresponding executable instructions to carry out the different operations as discussed herein.

As shown, computer system 1350 of the present example includes interconnect 1311 coupling computer readable storage media 1312 such as a non-transitory type of media (which can be any suitable type of hardware storage medium in which digital information can be stored and or retrieved), a processor 1313 (computer processor hardware), I/O interface 1314, and a communications interface 1317.

I/O interface(s) 1314 supports connectivity to repository 1380 and input resource 1392.

Computer readable storage medium 1312 can be any hardware storage device such as memory, optical storage, hard drive, floppy disk, etc. In one embodiment, the computer readable storage medium 1312 stores instructions and/or data.

As shown, computer readable storage media 1312 can be encoded with fabricator management application 140-1 (e.g., including instructions) in a respective wireless station to carry out any of the operations as discussed herein.

During operation of one embodiment, processor 1313 accesses computer readable storage media 1312 via the use of interconnect 1311 in order to launch, run, execute, interpret or otherwise perform the instructions in fabricator application 140-1 stored on computer readable storage medium 1312. Execution of the fabricator management application 140-1 produces fabricator management process 140-2 to carry out any of the operations and/or processes as discussed herein.

Those skilled in the art will understand that the computer system 1350 can include other processes and/or software and hardware components, such as an operating system that controls allocation and use of hardware resources to execute fabricator management application 140-1.

In accordance with different embodiments, note that computer system may reside in any of various types of devices, including, but not limited to, a mobile computer, a personal computer system, a wireless device, a wireless access point, a base station, phone device, desktop computer, laptop, notebook, netbook computer, mainframe computer system, handheld computer, workstation, network computer, application server, storage device, a consumer electronics device such as a camera, camcorder, set top box, mobile device, video game console, handheld video game device, a peripheral device such as a switch, modem, router, set-top box, content management device, handheld remote control device, any type of computing or electronic device, etc. The computer system 1350 may reside at any location or can be included in any suitable resource in any network environment to implement functionality as discussed herein.

Functionality supported by the different resources will now be discussed via flowcharts in FIG. 13. Note that the steps in the flowcharts below can be executed in any suitable order.

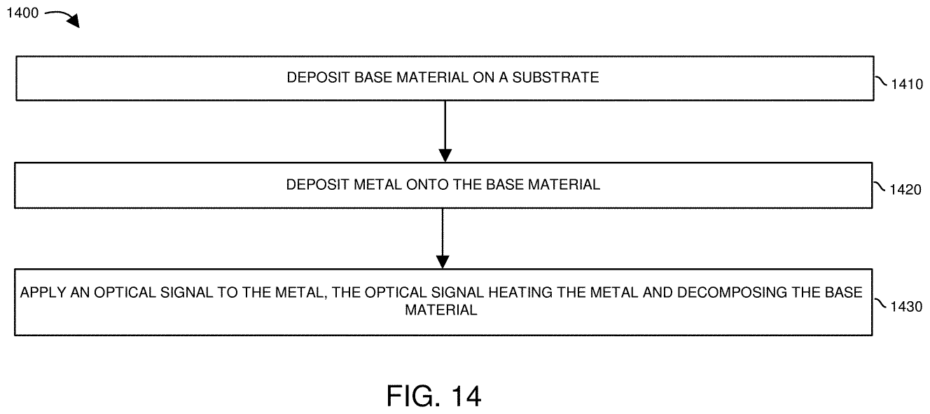

FIG. 14 is a flowchart 1400 illustrating an example method according to embodiments herein. Note that there will be some overlap with respect to concepts as discussed above.

In processing operation 1410, the fabricator 140 deposit base material 120 (such as particles) on a substrate 110.

In processing operation 1420, the fabricator 140 deposits metal material 130 onto the base material (such as particles 121, 122, 123, etc.).

In processing operation 1430, the fabricator 140 applies an optical signal 150 to the metal material on the particles. The optical signal 150 heats the metal material (such as layer of material 131, 132, 133, etc.) and decomposes the base material (such as particles 121, 122, 123, etc.).

Note again that techniques herein are well suited to facilitate use of a shared wireless channel amongst different types of wireless stations. However, it should be noted that embodiments herein are not limited to use in such applications and that the techniques discussed herein are well suited for other applications as well.

Based on the description set forth herein, numerous specific details have been set forth to provide a thorough understanding of claimed subject matter. However, it will be understood by those skilled in the art that claimed subject matter may be practiced without these specific details. In other instances, methods, apparatuses, systems, etc., that would be known by one of ordinary skill have not been described in detail so as not to obscure claimed subject matter. Some portions of the detailed description have been presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm as described herein, and generally, is considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has been convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a computing platform, such as a computer or a similar electronic computing device, that manipulates or transforms data represented as physical electronic or magnetic quantities within memories, registers, or other information storage devices, transmission devices, or display devices of the computing platform.

While this invention has been particularly shown and described with references to preferred embodiments thereof, it will be understood by those skilled in the art that various changes in form and details may be made therein without departing from the spirit and scope of the present application as defined by the appended claims. Such variations are intended to be covered by the scope of this present application. As such, the foregoing description of embodiments of the present application is not intended to be limiting. Rather, any limitations to the invention are presented in the following claims.

We claim:

1. A method comprising:
depositing base material on a substrate;
depositing metal onto the base material; and
applying an optical signal to the metal, the optical signal heating the metal and decomposing the base material.

2. The method as in claim 1, wherein depositing base material on a substrate includes: disposing nanoparticles on the substrate using nanosphere lithography.

3. The method as in claim 1, wherein the base material is a polymer material comprising multiple nanoparticles.

4. The method as in claim 3, wherein the polymer is selected from the group consisting of: polystyrene, polylactide, polylactide-polyglycolide copolymers, polycaprolactones, polyacrylates, poly(methyl methacrylate) (PMMA), polyethylene (PE), alginate, albumin, and chitosan.

5. The method as in claim 1, wherein application of the optical signal heats the metal above a melting point of the metal.

6. The method as in claim 1, wherein base material includes particles, the particles being a hexagonally packed monolayer on the substrate.

7. The method as in claim 6, wherein diameters of the particles fall within a range of about 25 nanometers to about 25 microns.

8. The method as in claim 1, wherein the base material is a non-metal material.

9. The method as in claim 1, wherein the deposited metal is a metal layer disposed on the base material; and
wherein a melting point of the base material is lower than a melting point of the metal.

10. The method of claim 1 further comprising:
controlling a magnitude of energy supplied by the optical signal to the metal to produce an array of hollow metal elements.

11. A system comprising:
fabricator operative to:
deposit base material on a substrate;
deposit metal onto the base material; and
apply an optical signal to the metal, the optical signal heating the metal and decomposing the base material.

12. The system as in claim 11, wherein base material includes particles applied via lithography.

13. The system as in claim 11, wherein the base material is a polymer material comprising multiple nanoparticles.

14. The system as in claim 13, wherein the polymer is selected from the group consisting of: polystyrene, polylactide, polylactide-polyglycolide copolymers, polycaprolactones, polyacrylates, poly(methyl methacrylate) (PMMA), polyethylene (PE), alginate, albumin, and chitosan.

15. The system as in claim 11, wherein application of the optical signal heats the metal above a melting point of the metal.

16. The system as in claim 11, wherein base material includes particles, the particles being a hexagonally packed monolayer on the substrate.

17. The system as in claim 16, wherein diameters of the particles fall within a range of about 25 nanometers to about 25 microns.

18. The system as in claim 11, wherein the deposited metal is a metal layer disposed on the base material; and
wherein a melting point of the base material is lower than a melting point of the metal.

19. The system of claim 11, wherein the fabricator is further operative to:
control a magnitude of energy supplied by the optical signal to the metal to produce an array of hollow metal elements.

20. Computer-readable storage hardware having instructions stored thereon, the instructions, when carried out by computer processor hardware, cause the computer processor hardware to:
deposit base material on a substrate;
deposit metal onto the base material; and
apply an optical signal to the metal, the optical signal heating the metal and decomposing the base material.
